(19) United States
(12) Patent Application Publication
(10) Pub. No.: US 2011/0068793 A1
(43) Pub. Date: Mar. 24, 2011

(54) SOLVATED HYPERPOLARIZED XeNMR AND MRI SIGNAL AMPLIFICATION BY GAS EXTRACTION

(75) Inventors: Alexander Pines, Berkeley, CA (US); Xin Zhou, Wuhan (CN); Dominic Graziani, Emeryville, CA (US)

(73) Assignee: The Regents of the University of California, Oakland, CA (US)

(21) Appl. No.: 12/887,423

(22) Filed: Sep. 21, 2010

Related U.S. Application Data
(60) Provisional application No. 61/244,389, filed on Sep. 21, 2009.

(51) Int. Cl. G01R 33/44

(52) U.S. Cl. 324/318

(57) ABSTRACT

The present invention provides a method and apparatus of amplifying the signal of at least one NMR spectrum and of at least one MRI of hyperpolarized xenon. In an embodiment, the invention includes dissolving the hyperpolarized xenon in a liquid via an input membrane, thereby resulting in xenon in liquid phase, encoding information in the longitudinal magnetization of the nuclear spins of the xenon in liquid phase via an encoding coil surrounding an encoding phantom coupled to an output of the input membrane and via an encoding magnet, thereby resulting in encoded xenon, extracting the encoded xenon into the gas phase from the liquid phase via an extraction membrane coupled to an output of the encoding phantom, thereby resulting in encoded xenon in the gas phase, and decoding the encoded information from the encoded xenon in gas phase via a detection coil coupled to an output of the extraction membrane.

### RELATED APPLICATIONS

The application claims priority to U.S. Provisional Patent Application Ser. No. 61/244,389, filed Sep. 21, 2009, which is herein incorporated by reference in its entirety.

### STATEMENT OF GOVERNMENT SUPPORT

This invention was made with government support under Contract No. DE-AC02-05CH11231 awarded by the U.S. Department of Energy. The government has certain rights in this invention.

### FIELD OF THE INVENTION

The present invention relates to the fields of nuclear magnetic resonance (NMR) and magnetic resonance imaging (MRI), and particularly relates to a method and apparatus of amplifying the signal of at least one nuclear magnetic resonance (NMR) spectrum and the signal of at least one magnetic resonance image (MRI) of hyperpolarized xenon.

### BACKGROUND OF THE INVENTION

NMR and MRI are non-ionizing and non-invasive techniques that allow for the visualization of opaque objects, such as a human brain and a human body. However, NMR and MRI suffer from low nuclear spin polarization at thermal equilibrium and/or low spin concentration.

The polarization of hyperpolarized xenon can be enhanced four or five orders of magnitude by spin-exchange optical pumping (SEOP), and could be utilized with xenon biosensors to detect cancer or tumor cells at the molecular level (i.e., molecular imaging). Hyperpolarized xenon has much longer longitudinal relaxation time (T1) in the gas phase than in the dissolved phase. Also, xenon in the gas phase has extremely long transverse relaxation time (T2) compared to solvated xenon in the liquid phase.

### PRIOR ART

Prior Art—Direct Detection of NMR or MRI

Prior art direct detection of NMR or MRI techniques requires a prohibitively large amount of signal averaging in order to obtain sufficient signal to noise ratio due to the prior art technique's small coil filling if the concentration of disease cells in a human brain or body is low (e.g. at the very early stage of a cancer or tumor). Prior art FIG. 1 shows a directly detected spectrum of ¹²⁹Xe dissolved in water from the Example described below. Such prior art direct detection systems, in order to increase the sensitivity of its NMR molecular imaging, usually need to average the NMR or MRI signal for long periods of time and thus are impractical in many situations. Also, prior art direct detection of NMR and MRI techniques are unable to provide both spatial and temporal information.

Prior Art—Remote Detection of NMR or MRI

Prior art remote detection, in which encoding and detection of spins are spatially separated and optimized, could alleviate the issue of small filling factor of the detection coil. However, such prior art remote detection techniques has only been employed in cases where the sample is encoded and detected in the same phase of matter. The low concentration of detected spins when dealing with solvated gases is the major challenge to overcome in order to make NMR and MRI a viable detection technique.

In order to detect disease at an early stage of the disease, a methodology to enhance the detection sensitivity of MRI is needed. Therefore, a method and apparatus of amplifying the signal of at least one nuclear magnetic resonance (NMR) spectrum and the signal of at least one magnetic resonance image (MRI) of hyperpolarized xenon is needed.

### SUMMARY OF THE INVENTION

The present invention provides a method and apparatus of amplifying the signal of at least one nuclear magnetic resonance (NMR) spectrum and the signal of at least one magnetic resonance image (MRI) of hyperpolarized xenon. In an exemplary embodiment, the method includes (1) dissolving the hyperpolarized xenon in a liquid via an input membrane, thereby resulting in xenon in liquid phase, (2) encoding information in the longitudinal magnetization of the nuclear spins of the xenon in the liquid phase via an encoding coil surrounding an encoding phantom coupled to an output of the input membrane and via an encoding magnet, thereby resulting in encoded xenon, (3) extracting the encoded xenon into the gas phase from the liquid phase via an extraction membrane coupled to an output of the encoding phantom, thereby resulting in encoded xenon in the gas phase, and (4) decoding the encoded information from the encoded xenon in the gas phase via a detection coil coupled to an output of the extraction membrane. In a further embodiment, the present invention further includes processing the decoded information to provide the NMR spectrum and the MRI from the hyperpolarized xenon via a processor logically coupled to an output of the detection coil.

In an exemplary embodiment, the apparatus includes (1) an input membrane operable to dissolve the hyperpolarized xenon in a liquid to result in xenon in liquid phase, (2) an encoding phantom coupled to an output of the input membrane, (3) an encoding coil surrounding the encoding phantom, where the encoding coil is operable to encode information in the longitudinal magnetization of the nuclear spins of the xenon in the liquid phase to result in encoded xenon, (4) an encoding magnet, where the encoding magnet is operable to encode information in the longitudinal magnetization of the nuclear spins of the xenon in the liquid phase to result in the encoded xenon, (5) an extraction membrane coupled to an output of the encoding phantom, where the extraction membrane is operable to extract the encoded xenon into the gas phase from the liquid phase to result in encoded xenon in the gas phase, and (6) a detection coil coupled to an output of the extraction membrane, where the detection coil is operable to decode the encoded information from the encoded xenon in the gas phase. In a further embodiment, the present invention further includes a processor logically coupled to an output of the detection coil, where the processor is configured to process the decoded information to provide the NMR spectrum and the MRI from the hyperpolarized xenon.

In an exemplary embodiment, the encoding includes encoding spatial information in the longitudinal magnetization of the nuclear spins of the xenon in the liquid phase via the encoding coil. In an exemplary embodiment, the encoding includes encoding temporal information in the longitudinal magnetization of the nuclear spins of the xenon in the liquid phase via the encoding coil. In an exemplary embodiment, the encoding includes encoding chemical shift information in the longitudinal magnetization of the nuclear spins of the xenon in the liquid phase via the encoding coil. In an exemplary embodiment, the encoding includes applying at least one radio frequency pulse to the xenon in the liquid phase via the encoding coil.

In an exemplary embodiment, the encoding includes encoding spatial information in the longitudinal magnetization of the nuclear spins of the xenon in the liquid phase via the encoding magnet. In an exemplary embodiment, the encoding includes applying at least one magnetic gradient to the xenon in the liquid phase via the encoding magnet.

In an exemplary embodiment, the encoding coil is operable to encode spatial information in the longitudinal magnetization of the nuclear spins of the xenon in the liquid phase. In an exemplary embodiment, the encoding coil is operable to encode temporal information in the longitudinal magnetization of the nuclear spins of the xenon in the liquid phase. In an exemplary embodiment, the encoding coil is operable to encode chemical shift information in the longitudinal magnetization of the nuclear spins of the xenon in the liquid phase. In an exemplary embodiment, the encoding coil is operable to apply at least one radio frequency pulse to the xenon in the liquid phase.

In an exemplary embodiment, the encoding magnet is operable to encode spatial information in the longitudinal magnetization of the nuclear spins of the xenon in the liquid phase. In an exemplary embodiment, the encoding magnet is operable to apply at least one magnetic gradient to the xenon in the liquid phase.

### BRIEF DESCRIPTION OF THE DRAWINGS

FIG. 1 is a directly detected spectrum of ¹²⁹Xe dissolved in water obtained from a prior art technique

FIG. 2A is a flowchart in accordance with an exemplary embodiment of the present invention.

FIG. 2B is a flowchart in accordance with an exemplary embodiment of the present invention.

FIG. 2C is a diagram in accordance with an exemplary embodiment of the present invention.

FIG. 2D is a diagram in accordance with an exemplary embodiment of the present invention.

FIG. 3A is a flowchart in accordance with an exemplary embodiment of the present invention.

FIG. 3B is a flowchart in accordance with an exemplary embodiment of the present invention.

FIG. 3C is a flowchart in accordance with an exemplary embodiment of the present invention.

FIG. 3D is a flowchart in accordance with an exemplary embodiment of the present invention.

FIG. 3E is a flowchart in accordance with an exemplary embodiment of the present invention.

FIG. 3F is a flowchart in accordance with an exemplary embodiment of the present invention.

FIG. 4 is a diagram of pulse sequence in accordance with an exemplary embodiment of the present invention.

FIG. 5 is a diagram of pulse sequence in accordance with an exemplary embodiment of the present invention.

FIG. 6 is a remotely detected spectrum of ¹²⁹Xe dissolved in water obtained via the present invention.

FIG. 7 shows time of flight (TOF) images of xenon dissolved in water obtained via the present invention.

### DETAILED DESCRIPTION OF THE INVENTION

The present invention provides a method and apparatus of amplifying the signal of at least one nuclear magnetic resonance (NMR) spectrum and the signal of at least one magnetic resonance image (MRI) of hyperpolarized xenon. In an exemplary embodiment, the method includes (1) dissolving the hyperpolarized xenon in a liquid via an input membrane, thereby resulting in xenon in liquid phase, (2) encoding information in the longitudinal magnetization of the nuclear spins of the xenon in the liquid phase via an encoding coil surrounding an encoding phantom coupled to an output of the input membrane and via an encoding magnet, thereby resulting in encoded xenon, (3) extracting the encoded xenon into the gas phase from the liquid phase via an extraction membrane coupled to an output of the encoding phantom, thereby resulting in encoded xenon in the gas phase, and (4) decoding the encoded information from the encoded xenon in the gas phase via a detection coil coupled to an output of the extraction membrane. In a further embodiment, the present invention further includes processing the decoded information to provide the NMR spectrum and the MRI from the hyperpolarized xenon via a processor logically coupled to an output of the detection coil.

In an exemplary embodiment, the apparatus includes (1) an input membrane operable to dissolve the hyperpolarized xenon in a liquid to result in xenon in liquid phase, (2) an encoding phantom coupled to an output of the input membrane, (3) an encoding coil surrounding the encoding phantom, where the encoding coil is operable to encode information in the longitudinal magnetization of the nuclear spins of the xenon in the liquid phase to result in encoded xenon, (4) an encoding magnet, where the encoding magnet is operable to encode information in the longitudinal magnetization of the nuclear spins of the xenon in the liquid phase to result in the encoded xenon, (5) an extraction membrane coupled to an output of the encoding phantom, where the extraction membrane is operable to extract the encoded xenon into the gas phase from the liquid phase to result in encoded xenon in the gas phase, and (6) a detection coil coupled to an output of the extraction membrane, where the detection coil is operable to decode the encoded information from the encoded xenon in the gas phase. In a further embodiment, the present invention further includes a processor logically coupled to an output of the detection coil, where the processor is configured to process the decoded information to provide the NMR spectrum and the MRI from the hyperpolarized xenon.

The present invention provides for the amplification of dissolved-phase hyperpolarized Xe NMR and MRI signal by gas extraction vitro. The present invention also encodes hyperpolarized xenon spin in dissolved blood or tissue and remotely detects exhaled xenon gas to achieve NMR spectral and/or image information. The present invention detects dissolved xenon via NMR and MRI at low concentrations with high efficiency.

The present invention provides a method and apparatus for solvated hyperpolarized xenon NMR and MRI signal amplification by gas extraction. The present invention obtains liquid phase NMR spectra and MRI images by remotely detecting the extracted hyperpolarized xenon in gas phase. With a xenon biosensor, the present invention could be used for in vivo human cancer or tumor cell detection by non-invasively detecting the exhaled xenon gas with a significant signal enhancement.

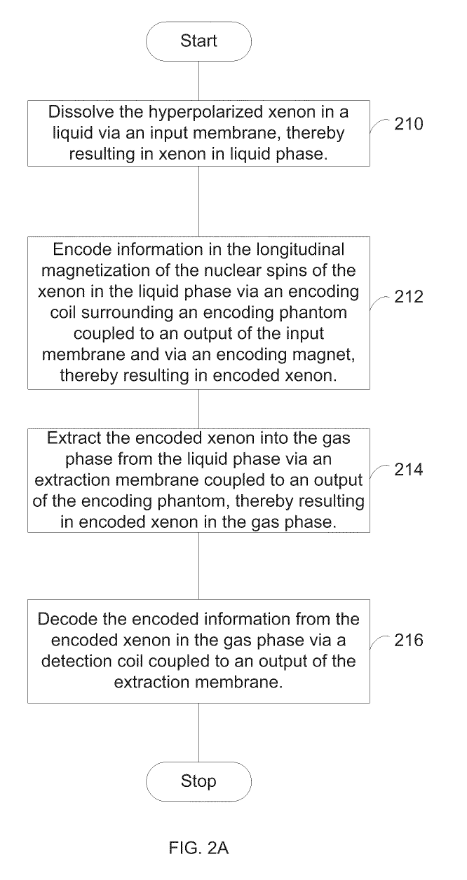

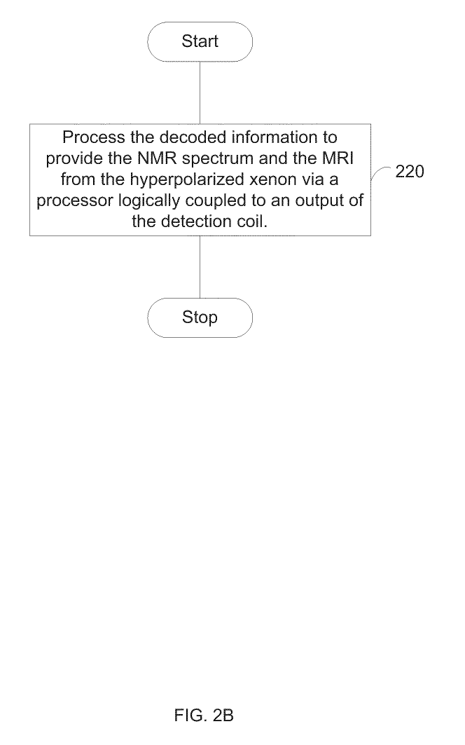

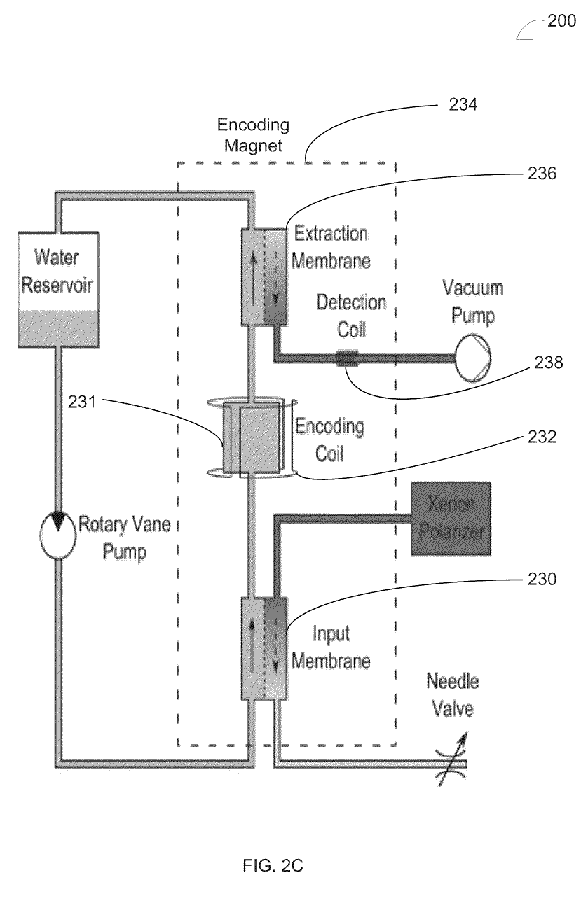

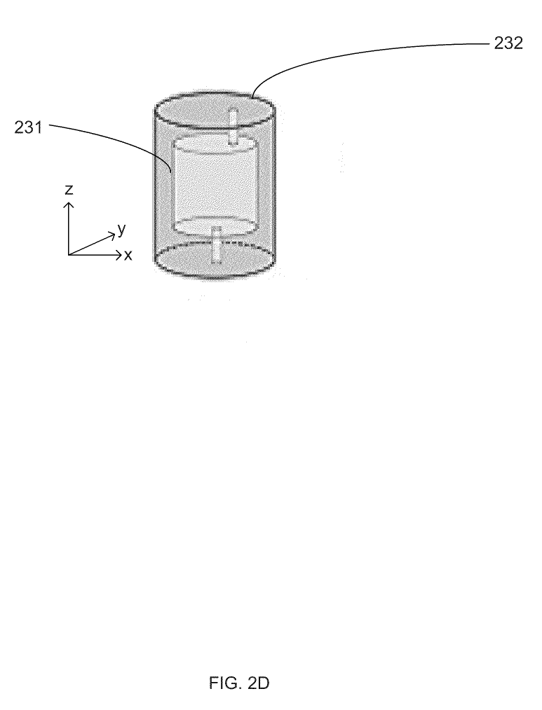

Referring to FIG. 2A, in an exemplary embodiment, the present invention includes a step 210 of dissolving the hyperpolarized xenon in a liquid via an input membrane, thereby resulting in xenon in liquid phase, a step 212 of encoding information in the longitudinal magnetization of the nuclear spins of the xenon in the liquid phase via an encoding coil surrounding an encoding phantom coupled to an output of the input membrane and via an encoding magnet, thereby resulting in encoded xenon, a step 214 of extracting the encoded xenon into the gas phase from the liquid phase via an extraction membrane coupled to an output of the encoding phantom, thereby resulting in encoded xenon in the gas phase, and a step 216 of decoding the encoded information from the encoded xenon in the gas phase via a detection coil coupled to an output of the extraction membrane. Referring to FIG. 2B, in a further embodiment, the present invention further includes a step 220 of processing the decoded information to provide the NMR spectrum and the MRI from the hyperpolarized xenon via a processor logically coupled to an output of the detection coil.

Referring to FIG. 2C, in an exemplary embodiment, the present invention includes an input membrane 230 operable to dissolve the hyperpolarized xenon in a liquid to result in xenon in liquid phase, an encoding phantom 231 coupled to an output of the input membrane, an encoding coil 232 surrounding encoding phantom 231, where the encoding coil is operable to encode information in the longitudinal magnetization of the nuclear spins of the xenon in the liquid phase to result in encoded xenon, an encoding magnet 234, where the encoding magnet is operable to encode information in the longitudinal magnetization of the nuclear spins of the xenon in the liquid phase to result in the encoded xenon, an extraction membrane 236 coupled to an output of encoding phantom 231, where the extraction membrane is operable to extract the encoded xenon into the gas phase from the liquid phase to result in encoded xenon in the gas phase, and a detection coil 238 coupled to an output of the extraction membrane, where the detection coil is operable to decode the encoded information from the encoded xenon in the gas phase. Referring to FIG. 2D, in an exemplary embodiment, encoding phantom 231 is surrounded by encoding coil 232, with the x, y, z spatial coordinates as shown.

In an exemplary embodiment, input membrane 230 dissolves xenon in water (in analogy to lung tissue dissolving xenon in blood). When the dissolved xenon in the water flows into encoding phantom 231, spatial, temporal, and chemical shift information is encoded and stored in the longitudinal magnetization of the xenon spins via radio frequency pulses emitted by encoding coil 232 and gradient field pulses applied by encoding magnet 234. Once the dissolved xenon travels to extraction membrane 236, xenon gas is extracted from the liquid due to the low pressure (like the lung's exhalation function) and flows into detection coil 238 where the information is decoded. The detected concentration of hyperpolarized xenon could be increased by either compressing or liquefying the extracted xenon gas, resulting in signal amplification. Processing the acquired data from detection coil 238 via a processor provides the NMR spectrum and MRI image from the sample in encoding coil 232.

### Encoding Information

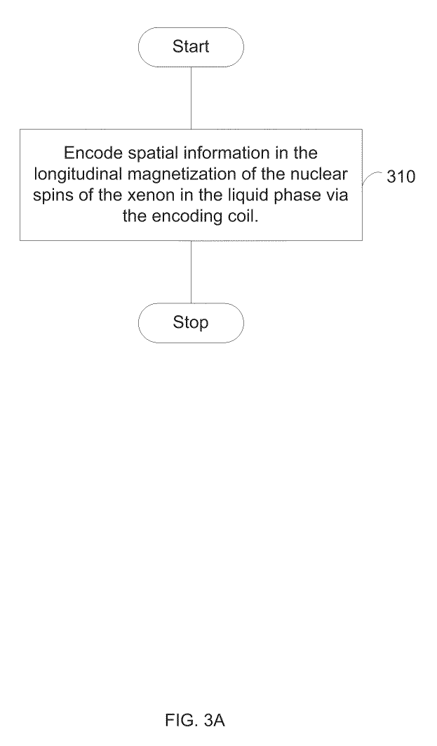

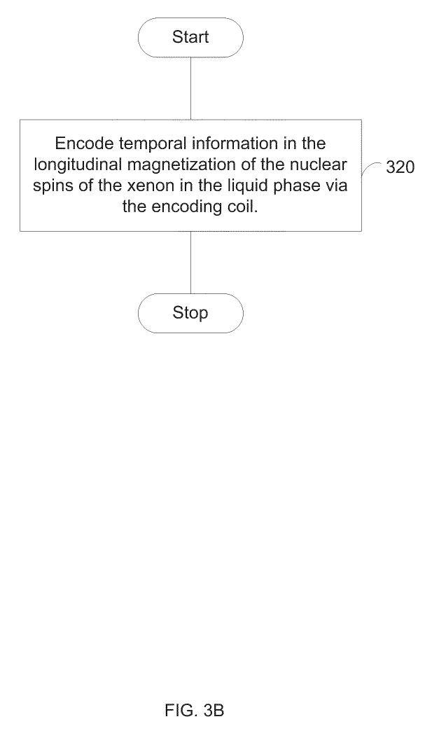

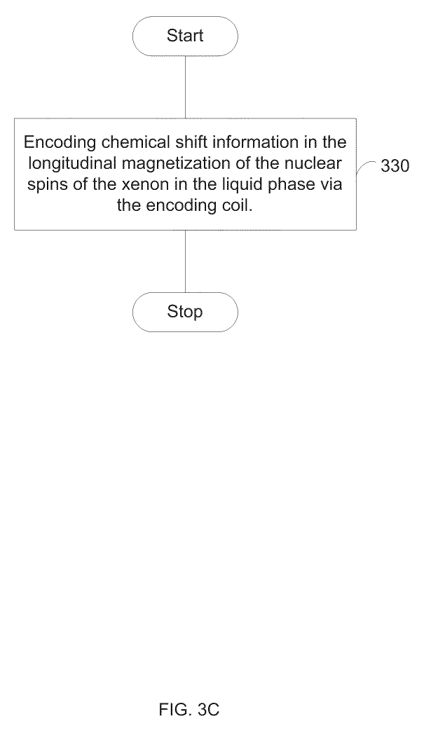

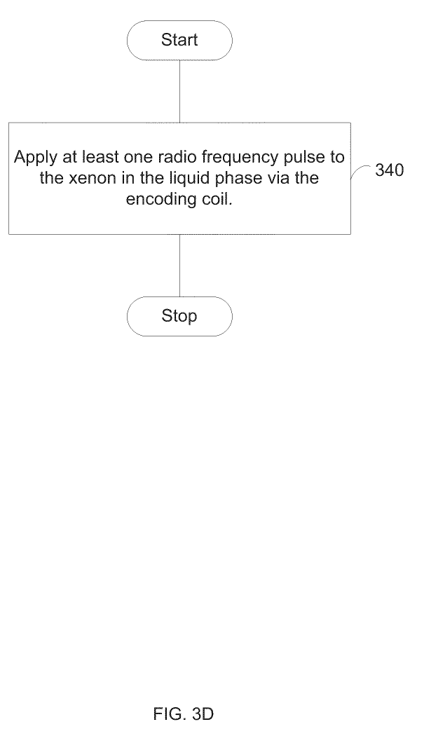

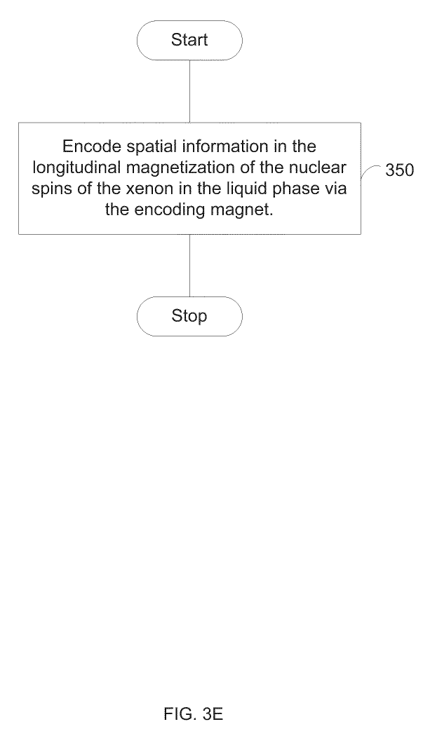

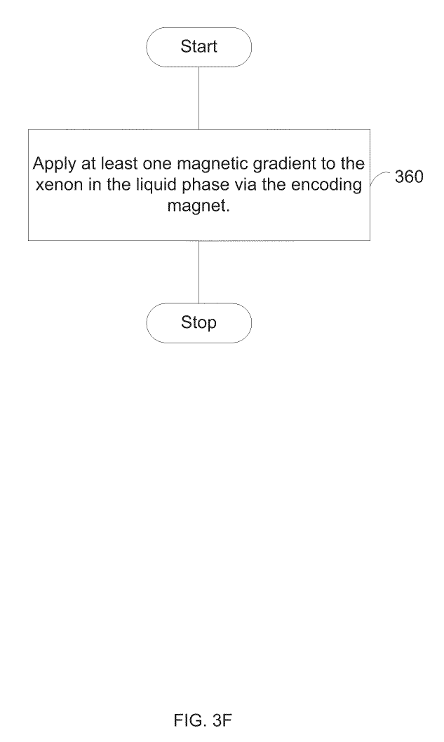

Referring to FIG. 3A, in an exemplary embodiment, encoding step 212 includes a step 310 of encoding spatial information in the longitudinal magnetization of the nuclear spins of the xenon in the liquid phase via encoding coil 232. Referring to FIG. 3B, in an exemplary embodiment, encoding step 212 includes a step 320 of encoding temporal information in the longitudinal magnetization of the nuclear spins of the xenon in the liquid phase via encoding coil 232. Referring to FIG. 3C, in an exemplary embodiment, encoding step 212 includes a step 330 of encoding chemical shift information in the longitudinal magnetization of the nuclear spins of the xenon in the liquid phase via encoding coil 232. Referring to FIG. 3D, in an exemplary embodiment, encoding step 212 includes a step 340 of applying at least one radio frequency pulse to the xenon in the liquid phase via encoding coil 232.

Referring to FIG. 3E, in an exemplary embodiment, encoding step 212 includes a step 350 of encoding spatial information in the longitudinal magnetization of the nuclear spins of the xenon in the liquid phase via encoding magnet 234. Referring to FIG. 3F, in an exemplary embodiment, encoding step 212 includes a step 360 of applying at least one magnetic gradient to the xenon in the liquid phase via encoding magnet 234.

### Acquiring NMR Spectrum

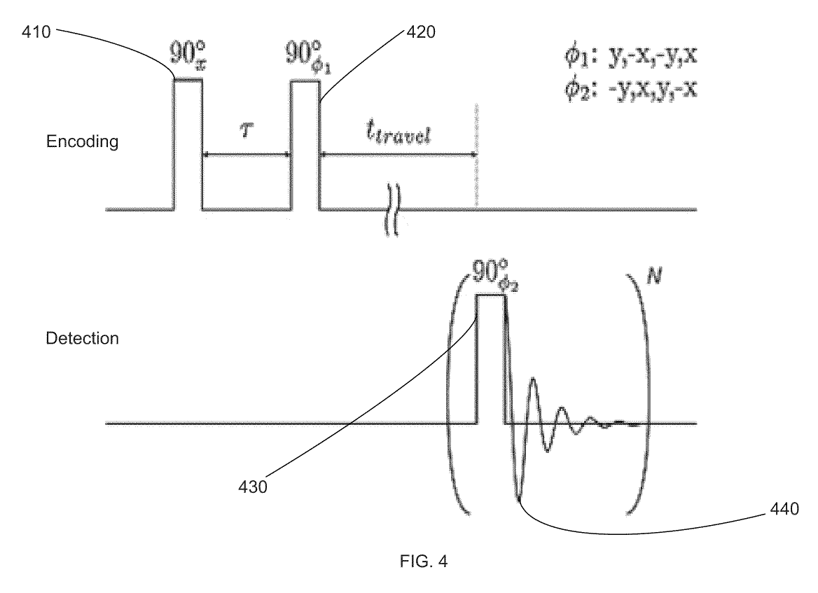

The present invention acquires NMR spectrum as depicted in FIG. 4. A first 90 degree pulse 410 emitted by encoding coil 232 tips the magnetization of dissolved hyperpolarized xenon into the transverse plane x. The spins are allowed to evolve under chemical shift for a delay time τ; at which point a second 90 degree pulse 420 emitted by encoding coil 232 is applied to store information along the longitudinal axis φ₁. The encoded information travels for a time tₜᵣₐᵥₑₗ; at which point the encoded information reaches detection coil 238, and a series of 90 pulses 430 and subsequent acquisitions are applied by detection coil 238. By arraying delay time τ, the free induction decay (FID) 440 in the encoding region can be reconstructed point by point via acquisition in detection coil 238.

### Acquiring MRI

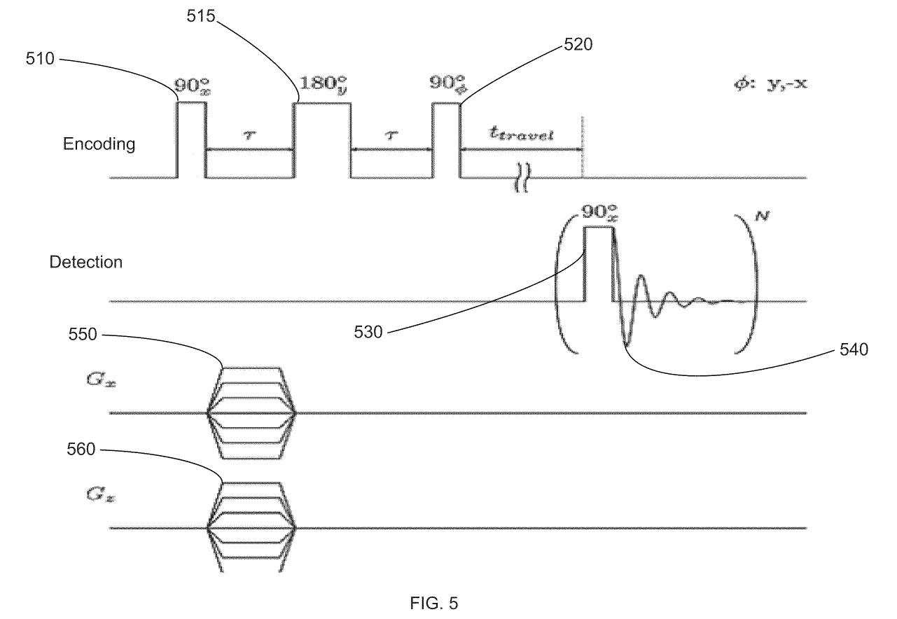

The present invention acquires MRI as depicted in FIG. 5. A first 90 degree pulse 510 emitted by encoding coil 232 tips the magnetization of dissolved hyperpolarized xenon into the transverse plane x. Magnetic gradients for phase encoding are applied by encoding magnet 234 after the first 90 degree pulse 510, which encodes spatial information in the x and z directions on the spins. After a first delay time τ; a 180 degree pulse 515 is applied by encoding coil 232 after the application of the magnetic gradients for the phase encoding, thereby compensating for dephasing due to inhomogeneity of a static magnetic field. After a second delay time τ; a second 90 degree pulse 520 is applied by encoding coil 232 to store information along the longitudinal axis φ. The encoded information travels for a time tₜᵣₐᵥₑₗ; at which point the encoded information reaches detection coil 238, and a series of 90 pulses 530 and subsequent acquisitions are applied by detection coil 238. By arraying delay time τ, the free induction decay (FID) 540 in the encoding region can be reconstructed point by point via acquisition in detection coil 238. Then, an MRI is obtained by applying Fourier transforms Gₓ 550 and G_{z} 560 to the two phase encoded dimensions, x and z.

### Signal Amplification

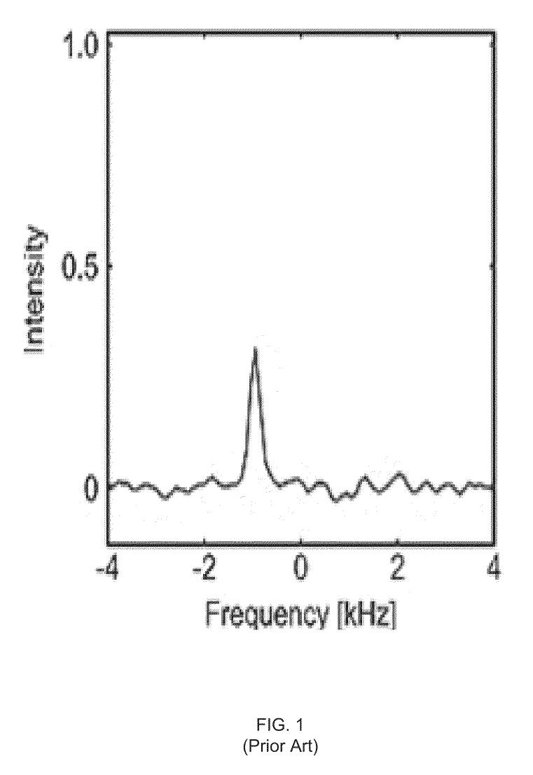

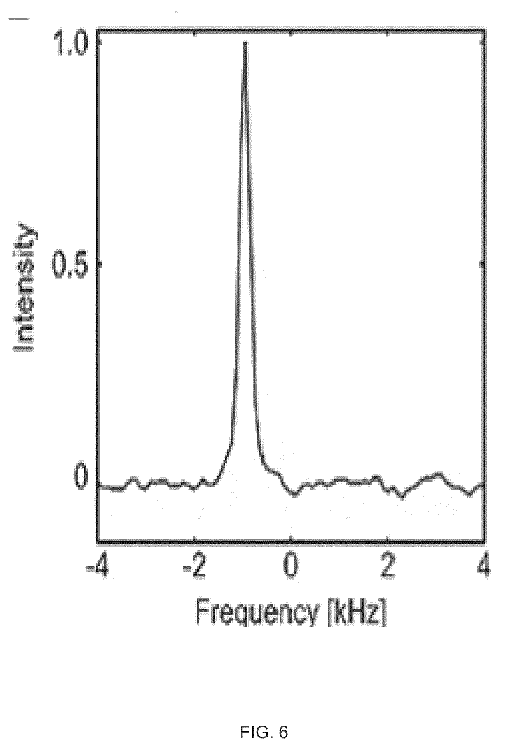

The present invention provides a method of acquiring amplified liquid phase NMR spectrum and MRI image. The present invention extracts hyperpolarized xenon gas from a liquid (e.g., from the blood through the lung exhalation function) and then either compresses the extracted hyperpolarized xenon gas into very dense high-pressure gas or liquefies it into hyperpolarized liquid xenon, for the detection, resulting in a signal amplification due to an increased detected spin density. This results in an increase in signal to noise ratio in the resulting detected signal, as exemplified in experimental data from the experiments described in U.S. Provisional Patent Application Ser. No. 61/244,389, filed Sep. 21, 2009, which is herein incorporated by reference in its entirety, shown in FIG. 6 (when compared to prior art experimental data from those experiments, shown in FIG. 1).

### Time of Flight (TOF) Information

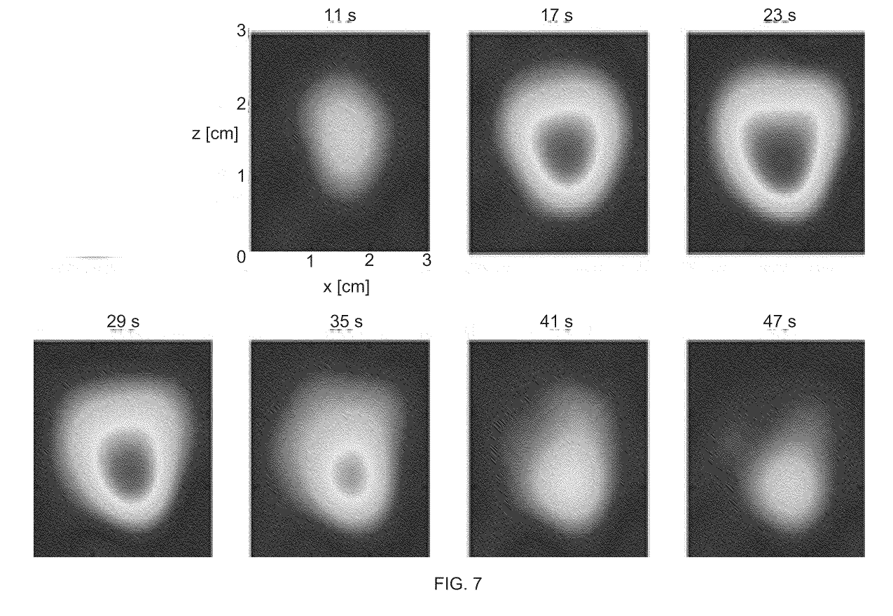

The present invention provides both spatial and temporal information, as exemplified in time of flight (TOF) information from the experiments described in U.S. Provisional Patent Application Ser. No. 61/244,389, filed Sep. 21, 2009, which is herein incorporated by reference in its entirety, shown in FIG. 7.

### Spin Polarization Information

The present invention allows for the preservation of the spin polarization information in the xenon (preserved during the phase transition from liquid phase to gas phase). As a result, the present invention can obtain images with high signal to noise ratio from extremely low concentrations of dissolved gas in the body via exhalation non-invasively and in vivo.

### General

The present invention allows for encoded information in the xenon to persist long enough to allow for accumulation of extracted xenon gas for compression. Additionally, the present invention allows for additional signal amplification (i) by decreasing the linewidth in a well shimmed magnet or (ii) through signal averaging with an echo train. The present invention analyzes complex time dependent processes such as gas exchange in the lungs and xenon penetration of the blood-brain barrier (where the xenon may bind to disease cells).

### EXAMPLE

The invention will be described in greater detail by way of a specific example. The following example is offered for illustrative purposes, and is intended neither to limit nor define the invention in any manner.

Materials and Methods

Hyperpolarized Xenon

A homebuilt xenon polarizer produces hyperpolarized ¹²⁹Xe by spin-exchange optical pumping (See Walker T G, Happer W., “Spin-exchange optical pumping of noble-gas nuclei”, Rev Mod Phys. 1997; 69:629-642). The apparatus is similar to that in Zhou X, et al., “Experimental and dynamic simulations of radiation damping of laser-polarized liquid ¹²⁹Xe at low magnetic field in a flow system”, Appl Magn Reson. 2004; 26:327-337, except that the current setup allows for continuous gas flow. A gas mixture of 2% natural abundance Xe, 2% N2, and 96% He flows through an optical pumping cell filled with Rb vapor at 140° C. Three laser diode arrays optically pump the Rb at 794.7 nm with 110 W of total laser power. Typical polarization levels of 8-10% are achieved at a flow rate of 0.5 standard liters per minute (SLPM).

Flow Setup

Hyperpolarized ¹²⁹Xe is dissolved and extracted in three independent flow paths as depicted in FIG. 2C. Xenon flows from the polarizer at 0.5 SLPM and a pressure of 50 psi (340 kPa), where it encounters input membrane 230, the first of two membrane modules (Membrana model G543; 16-mL liquid volume, 25-mL gas volume). Input membrane 230 allows the gas to come into contact with recirculating distilled water pressurized to 80 psi (550 kPa) and flowing at a rate of 2 mL/s. The large surface area of input membrane 230 enables rapid dissolution of hyperpolarized xenon into the water. The water then flows into encoding phantom 231, a cylindrical phantom (10.8 mL), inside encoding coil 232, a 38-mm saddle-shaped encoding coil, where the NMR information is encoded into the longitudinal magnetization at 9.4 T. The solvated xenon continues flowing to extraction membrane 236, a second membrane module (Membrana model G591; ≈1-mL liquid volume, 2.7-mL gas volume), where it is extracted from the liquid under a vacuum of 4 psi (28 kPa). The extracted gas is then detected with a 3.2-mm i.d., 1-cm long solenoid detection coil 238 with a detection volume of 0.02 mL.

Pulse Sequences

The pulse sequences for the remotely detected spectrum and the remotely detected TOF images are depicted in FIG. 4 and FIG. 5, respectively. Both sequences follow the basic remote detection format where the magnetization in the encoding volume is excited, allowed to evolve, and then stored to the longitudinal axis. The encoded spins then flow to the detection coil where the z-magnetization is read out with a series of excitation pulses. Because each storage pulse only stores one component of the magnetization, a minimum of two phase cycles is needed to collect both the real and imaginary components of the data.

For the remotely detected spectrum, the spins are allowed to evolve under chemical shift for a time τ, which is then incremented to reconstruct the free induction decay (FID) point by point. To acquire the TOF images, the spins evolve under two phase encode gradients applied in the z and x directions to encode the spatial information. A 180° pulse is then applied at a time τ to refocus the effects of any static field inhomogeneities. Finally, at time 2τ, the encoded information is stored along the z axis and the spins flow to detection coil 238 to be decoded. A four-step phase cycle involving both the storage and detection pulses was used to acquire the remote spectrum to remove the baseline offset of the FID produced by unencoded spins in detection coil 238. The TOF images were collected with only a two-step phase cycle of the storage pulse to save on acquisition time.

Data Reconstruction

Spectrum

Because of the four-step phase cycle used in acquiring the remote spectrum, only encoded spins contribute to the signal in detection coil 238. Optimal signal-to-noise can be obtained by acquiring the entire encoded volume in one acquisition; however, because of the large volume of extracted gas compared with the detection volume, the encoded spins were detected over 60 acquisitions. Each FID collected from the individual detection pulses was first apodized with a matched exponential function, and then Fourier-transformed. All points in the TOF dimension were added together to reproduce as much of the original signal from the sample in encoding phantom 231 as possible. This process was repeated over the bandwidth of the detected gas signal, and each reconstructed FID was added to produce the final remotely detected FID. Both the remotely detected and directly detected signals were first zero-filled from the original 41 points to a total of 82 points and apodized with the same Hamming function to reduce truncation artifacts before Fourier transformation.

Images

The TOF images were processed in a similar manner as the remote spectrum, with baseline correction applied to remove a dc offset caused by the reduced two-step phase cycle. Additionally, the TOF dimension was exploited to reconstruct images as a function of the time taken to reach the detector. Each TOF image was averaged over 12 TOF points. All images were acquired with a resolution of ≈6 mm and seven phase encode steps in each dimension. Data were apodized with a Gaussian function and zero-filled to 64×64 points before Fourier transforming.

### RESULTS

### Spectrum

FIG. 6 shows a remotely detected spectrum of ¹²⁹Xe dissolved in water obtained via the present invention, as opposed to prior art FIG. 1, which shows directly detected spectrum of ¹²⁹Xe dissolved in water obtained by a prior art direct detection technique. The spectra in FIG. 1 and FIG. 6 were scaled by their respective noise levels, and an intensity of 1.0 was assigned to the maximum signal in the remote spectrum. The same ¹²⁹Xe sample was used in both experiments with the detection coil of the direct spectrum being used as encoding coil 232 for the remote spectrum. Xenon gas is extracted from the encoding volume and flows to detection coil 238 in the remote experiment, resulting in an increased concentration of hyperpolarized Xe and hence an increase in signal to noise ration (SNR) of approximately 3. Despite being detected at a later time, in a different location, and a different physical state, the original xenon in water spectrum is reproduced exactly, as shown in FIG. 6.

Images

FIG. 7 shows TOF images, obtained by the present invention, of xenon dissolved in water continuously flowing through encoding phantom 231. Each image in FIG. 7 is labeled with its average TOF. The flow is along the positive z-direction, as shown in FIG. 2D, and as such, signal from the top of encoding phantom 231 at the outlet reaches detection coil 238 first. Over time, successive portions of the encoded volume are detected until the remaining signal is recovered after 47 s of travel time. The absence of signal at the bottom edges of encoding phantom 231 is likely caused by flow vortices at the inlet preventing the xenon spins from reaching the detector within the longitudinal relaxation time.

### ADDITIONAL DOCUMENTS INCORPORATED BY REFERENCE

The following additional documents are hereby incorporated by reference:

1. U.S. Provisional Patent Application Ser. No. 60/014,321, filed Mar. 29, 1996;

2. U.S. Pat. No. 6,426,058, filed Mar. 28, 1997, issued Jul. 30, 2002;

3. U.S. Pat. No. 6,818,202, filed Jun. 5, 2002, issued Nov. 16, 2004;

4. U.S. Patent Application Publication No. 2002/0094317, filed Mar. 28, 1997;

5. U.S. Patent Application Publication No. 2003/0017110, filed Jun. 5, 2002;

6. U.S. Patent Application Publication No. 2005/0030026, filed Sep. 13, 2004;

7. U.S. Provisional Patent Application Ser. No. 60/355,577, filed Feb. 6, 2002;

8. U.S. Pat. No. 6,885,192, filed Feb. 6, 2003, issued Apr. 26, 2005;

9. U.S. Pat. No. 7,053,610, filed Nov. 22, 2004, issued May 30, 2006;

10. U.S. Pat. No. 7,116,102, filed Mar. 27, 2006, issued Oct. 3, 2006;

11. U.S. Pat. No. 7,218,104, filed Sep. 25, 2006, issued May 15, 2007;

12. U.S. Pat. No. 7,466,132, filed Apr. 26, 2007, issued Dec. 16, 2008;

13. “Hyperpolarized xenon NMR and MRI signal amplification by gas extraction”, Xin Zhou, Dominic Graziani, and Alexander Pines, Proceedings of the National Academy of Sciences of the United States of America, 2009 Oct. 6, 106(40): 16903-16906.

### CONCLUSION

It is to be understood that the above description and examples are intended to be illustrative and not restrictive. Many embodiments will be apparent to those of skill in the art upon reading the above description and examples. The scope of the invention should, therefore, be determined not with reference to the above description and examples, but should instead be determined with reference to the appended claims, along with the full scope of equivalents to which such claims are entitled. The disclosures of all articles and references, including patent applications and publications, are incorporated herein by reference for all purposes.

What is claimed is:

1. A method of amplifying the signal of at least one nuclear magnetic resonance (NMR) spectrum and the signal of at least one magnetic resonance image (MRI) of hyperpolarized xenon, the method comprising:
dissolving the hyperpolarized xenon in a liquid via an input membrane, thereby resulting in xenon in liquid phase;
encoding information in the longitudinal magnetization of the nuclear spins of the xenon in the liquid phase via an encoding coil surrounding an encoding phantom coupled to an output of the input membrane and via an encoding magnet, thereby resulting in encoded xenon;
extracting the encoded xenon into the gas phase from the liquid phase via an extraction membrane coupled to an output of the encoding phantom, thereby resulting in encoded xenon in the gas phase; and
decoding the encoded information from the encoded xenon in the gas phase via a detection coil coupled to an output of the extraction membrane.

2. The method of claim 1 wherein the encoding comprises encoding spatial information in the longitudinal magnetization of the nuclear spins of the xenon in the liquid phase via the encoding coil.

3. The method of claim 1 wherein the encoding comprises encoding temporal information in the longitudinal magnetization of the nuclear spins of the xenon in the liquid phase via the encoding coil.

4. The method of claim 1 wherein the encoding comprises encoding chemical shift information in the longitudinal magnetization of the nuclear spins of the xenon in the liquid phase via the encoding coil.

5. The method of claim 1 wherein the encoding comprises applying at least one radio frequency pulse to the xenon in the liquid phase via the encoding coil.

6. The method of claim 1 wherein the encoding comprises encoding spatial information in the longitudinal magnetization of the nuclear spins of the xenon in the liquid phase via the encoding magnet.

7. The method of claim 1 wherein the encoding comprises applying at least one magnetic gradient to the xenon in the liquid phase via the encoding magnet.

8. The method of claim 1 wherein the method further comprises processing the decoded information to provide the NMR spectrum and the MRI from the hyperpolarized xenon via a processor logically coupled to an output of the detection coil.

9. An apparatus for amplifying the signal of at least one nuclear magnetic resonance (NMR) spectrum and the signal of at least one magnetic resonance image (MRI) of hyperpolarized xenon, the apparatus comprising:
an input membrane operable to dissolve the hyperpolarized xenon in a liquid to result in xenon in liquid phase;
an encoding phantom coupled to an output of the input membrane;
an encoding coil surrounding the encoding phantom, wherein the encoding coil is operable to encode information in the longitudinal magnetization of the nuclear spins of the xenon in the liquid phase to result in encoded xenon;
an encoding magnet, wherein the encoding magnet is operable to encode information in the longitudinal magnetization of the nuclear spins of the xenon in the liquid phase to result in the encoded xenon;
an extraction membrane coupled to an output of the encoding phantom, wherein the extraction membrane is operable to extract the encoded xenon into the gas phase from the liquid phase to result in encoded xenon in the gas phase; and
a detection coil coupled to an output of the extraction membrane, wherein the detection coil is operable to decode the encoded information from the encoded xenon in the gas phase.

10. The apparatus of claim 9 wherein the encoding coil is operable to encode spatial information in the longitudinal magnetization of the nuclear spins of the xenon in the liquid phase.

11. The apparatus of claim 9 wherein the encoding coil is operable to encode temporal information in the longitudinal magnetization of the nuclear spins of the xenon in the liquid phase.

12. The apparatus of claim 9 wherein the encoding coil is operable to encode chemical shift information in the longitudinal magnetization of the nuclear spins of the xenon in the liquid phase.

13. The apparatus of claim 9 wherein the encoding coil is operable to apply at least one radio frequency pulse to the xenon in the liquid phase.

14. The apparatus of claim 9 wherein the encoding magnet is operable to encode spatial information in the longitudinal magnetization of the nuclear spins of the xenon in the liquid phase.

15. The apparatus of claim 9 wherein the encoding magnet is operable to apply at least one magnetic gradient to the xenon in the liquid phase.

16. The apparatus of claim 9 wherein the apparatus further comprises a processor logically coupled to an output of the detection coil, wherein the processor is configured to process the decoded information to provide the NMR spectrum and the MRI from the hyperpolarized xenon.

17. A method of amplifying the signal of at least one magnetic resonance image (MRI) of hyperpolarized xenon, the method comprising:
dissolving the hyperpolarized xenon in a liquid via an input membrane, thereby resulting in xenon in liquid phase;
encoding information in the longitudinal magnetization of the nuclear spins of the xenon in the liquid phase via an encoding coil surrounding an encoding phantom coupled to an output of the input membrane and via an encoding magnet, thereby resulting in encoded xenon;
extracting the encoded xenon into the gas phase from the liquid phase via an extraction membrane coupled to an output of the encoding phantom, thereby resulting in encoded xenon in the gas phase; and
decoding the encoded information from the encoded xenon in the gas phase via a detection coil coupled to an output of the extraction membrane.

18. The method of claim 17 wherein the encoding comprises encoding spatial information in the longitudinal magnetization of the nuclear spins of the xenon in the liquid phase via the encoding coil.

19. The method of claim 17 wherein the encoding comprises encoding temporal information in the longitudinal magnetization of the nuclear spins of the xenon in the liquid phase via the encoding coil.

20. The method of claim 17 wherein the encoding comprises encoding chemical shift information in the longitudinal magnetization of the nuclear spins of the xenon in the liquid phase via the encoding coil.

21. The method of claim 17 wherein the encoding comprises applying at least one radio frequency pulse to the xenon in the liquid phase via the encoding coil.

22. The method of claim 17 wherein the encoding comprises encoding spatial information in the longitudinal magnetization of the nuclear spins of the xenon in the liquid phase via the encoding magnet.

23. The method of claim 17 wherein the encoding comprises applying at least one magnetic gradient to the xenon in the liquid phase via the encoding magnet.

24. The method of claim 17 wherein the method further comprises processing the decoded information to provide the MRI from the hyperpolarized xenon via a processor logically coupled to an output of the detection coil.

25. An apparatus for amplifying the signal of at least one magnetic resonance image (MRI) of hyperpolarized xenon, the apparatus comprising:
an input membrane operable to dissolve the hyperpolarized xenon in a liquid to result in xenon in liquid phase;
an encoding phantom coupled to an output of the input membrane;
an encoding coil surrounding the encoding phantom, wherein the encoding coil is operable to encode information in the longitudinal magnetization of the nuclear spins of the xenon in the liquid phase to result in encoded xenon;
an encoding magnet, wherein the encoding magnet is operable to encode information in the longitudinal magnetization of the nuclear spins of the xenon in the liquid phase to result in the encoded xenon;
an extraction membrane coupled to an output of the encoding phantom, wherein the extraction membrane is operable to extract the encoded xenon into the gas phase from the liquid phase to result in encoded xenon in the gas phase; and
a detection coil coupled to an output of the extraction membrane, wherein the detection coil is operable to decode the encoded information from the encoded xenon in the gas phase.

26. The apparatus of claim 25 wherein the encoding coil is operable to encode spatial information in the longitudinal magnetization of the nuclear spins of the xenon in the liquid phase.

27. The apparatus of claim 25 wherein the encoding coil is operable to encode temporal information in the longitudinal magnetization of the nuclear spins of the xenon in the liquid phase.

28. The apparatus of claim 25 wherein the encoding coil is operable to encode chemical shift information in the longitudinal magnetization of the nuclear spins of the xenon in the liquid phase.

29. The apparatus of claim 25 wherein the encoding coil is operable to apply at least one radio frequency pulse to the xenon in the liquid phase.

30. The apparatus of claim 25 wherein the encoding magnet is operable to encode spatial information in the longitudinal magnetization of the nuclear spins of the xenon in the liquid phase.

31. The apparatus of claim 25 wherein the encoding magnet is operable to apply at least one magnetic gradient to the xenon in the liquid phase.

32. The apparatus of claim 25 wherein the apparatus further comprises a processor logically coupled to an output of the detection coil, wherein the processor is configured to process the decoded information to provide the MRI from the hyperpolarized xenon.

33. A method of amplifying the signal of at least one nuclear magnetic resonance (NMR) spectrum of hyperpolarized xenon, the method comprising:
dissolving the hyperpolarized xenon in a liquid via an input membrane, thereby resulting in xenon in liquid phase;
encoding information in the longitudinal magnetization of the nuclear spins of the xenon in the liquid phase via an encoding coil surrounding an encoding phantom coupled to an output of the input membrane, thereby resulting in encoded xenon;
extracting the encoded xenon into the gas phase from the liquid phase via an extraction membrane coupled to an output of the encoding phantom, thereby resulting in encoded xenon in the gas phase; and
decoding the encoded information from the encoded xenon in the gas phase via a detection coil coupled to an output of the extraction membrane.

34. The method of claim 33 wherein the encoding comprises encoding spatial information in the longitudinal magnetization of the nuclear spins of the xenon in the liquid phase via the encoding coil.

35. The method of claim 33 wherein the encoding comprises encoding temporal information in the longitudinal magnetization of the nuclear spins of the xenon in the liquid phase via the encoding coil.

36. The method of claim 33 wherein the encoding comprises encoding chemical shift information in the longitudinal magnetization of the nuclear spins of the xenon in the liquid phase via the encoding coil.

37. The method of claim 33 wherein the encoding comprises applying at least one radio frequency pulse to the xenon in the liquid phase via the encoding coil.

38. The method of claim 33 wherein the method further comprises processing the decoded information to provide the NMR spectrum from the hyperpolarized xenon via a processor logically coupled to an output of the detection coil.

39. An apparatus for amplifying the signal of at least one nuclear magnetic resonance (NMR) spectrum of hyperpolarized xenon, the apparatus comprising:
an input membrane operable to dissolve the hyperpolarized xenon in a liquid to result in xenon in liquid phase;
an encoding phantom coupled to an output of the input membrane;
an encoding coil surrounding the encoding phantom, wherein the encoding coil is operable to encode information in the longitudinal magnetization of the nuclear spins of the xenon in the liquid phase to result in encoded xenon;
an extraction membrane coupled to an output of the encoding phantom, wherein the extraction membrane is operable to extract the encoded xenon into the gas phase from the liquid phase to resulting in encoded xenon in the gas phase; and
a detection coil coupled to an output of the extraction membrane, wherein the detection coil is operable to decode the encoded information from the encoded xenon in the gas phase.

40. The apparatus of claim 39 wherein the encoding coil is operable to encode spatial information in the longitudinal magnetization of the nuclear spins of the xenon in the liquid phase.

41. The apparatus of claim 39 wherein the encoding coil is operable to encode temporal information in the longitudinal magnetization of the nuclear spins of the xenon in the liquid phase.

42. The apparatus of claim 39 wherein the encoding coil is operable to encode chemical shift information in the longitudinal magnetization of the nuclear spins of the xenon in the liquid phase.

43. The apparatus of claim 39 wherein the encoding coil is operable to apply at least one radio frequency pulse to the xenon in the liquid phase.

44. The apparatus of claim 39 wherein the apparatus further comprises a processor logically coupled to an output of the detection coil, wherein the processor is configured to process the decoded information to provide the NMR spectrum from the hyperpolarized xenon.
